(19) United States
(12) Patent Application Publication
(10) Pub. No.: US 2025/0035423 A1
(43) Pub. Date: Jan. 30, 2025

(54) METHOD FOR RECOGNIZING A TARGET MAGNET ORIENTATION IN A MAGNETIC POSITION SENSOR

(71) Applicant: Balluff GmbH, Neuhausen a.d.F. (DE)

(72) Inventors: Zoltan Kantor, Nemesvamos (HU); Robert Weisz, Veszprem (HU)

(21) Appl. No.: 18/753,346

(22) Filed: Jun. 25, 2024

(30) Foreign Application Priority Data
Jul. 27, 2023 (DE) 10 2023 120 070.4

(51) Int. Cl. G01B 7/30; G01B 7/00; G01R 33/02

(52) U.S. Cl. CPC G01B 7/30; G01B 7/003; G01R 33/0206

(57) ABSTRACT

The method disclosed herein for determining the orientation of a target magnet (120) in a magnetic position sensor, in particular in a magnetic position sensor with a sensor array (100) having a number of at least three sensor elements (105-115), has the following steps in particular:
gathering (1100) a number of magnetic vector data;
calculating (1105) vector angle data from the gathered vector data and calculating (1110) progressions of the gathered vector data;
monotonizing (1115, 1120) the calculated vector angle data for at least two predefined specific sets of circumstances, that is to say by increasing or reducing individual angle values of the calculated vector angle data;
excluding (1125) at least one of the at least two predefined specific sets of circumstances on the basis of the monotonized vector angle data;
calculating (1135) expected progressions for non-excluded specific sets of circumstances;
determining (1140) the orientation of the target magnet (120) using the calculated (1110) progressions of gathered vector data and the calculated (1135), expected progressions.

The present invention relates to a method for detecting a target magnet orientation in a magnetic position sensor, that is to say preferably in a magnetic position sensor with a sensor array.

Magnetic field position measurement systems (referred to below as “BMP sensors”) developed and distributed by the applicant measure with only axially directed magnets.

EP3428582B1 discloses a sensor array with two sensor elements preferably involved here. This sensor operates both with positively and with negatively oriented or aligned, axially and radially arranged magnets, the requisite linearization of the output signal depending on the magnet alignment. The magnet alignment is determined here by the respective sign of the axial and radial magnetic field vector components that are measured by the two sensor elements.

However, in certain areas of the detection area as a whole, it is impossible to distinguish between different magnet arrangements solely on the basis of the actual sign of said magnetic field vector components. Due consideration also has to be given to the relationship between the spatial derivations of the magnetic field components even in only short magnet movements.

However, an initially as yet unknown alignment or orientation of the magnet can be ascertained or identified in certain areas of the detection area, but only if the magnet is moved. Since analysis algorithms in position sensors involved here can operate both with radially and with axially arranged target magnets, it is in any case advantageous to know the arrangement or orientation of the target magnets.

The arrangement of the sensor elements is already preset during their production according to the prior art. As a result, for each sensor element, the sensitive axes of the corrected scanning of the individual microchips are aligned parallel to the x-, y- or z-axis of the scanning device, i.e. the rotation and inclination errors arising during assembly are corrected individually for each chip.

The Δx and Δz shift errors of the chips constructed in this way are also either known or negligible, so they are disregarded below. It is also assumed below that the fluctuations in sensitivity of the sensor elements have already been compensated.

The abovementioned alignment or orientation problems with the target magnet according to the prior art are also moved or transformed to the x-z plane, the line of movement of the target magnet substantially coming to lie in the x-z plane and also running parallel to the x-direction, i.e. the sensitive axis. The magnetic moment of the target magnet is also aligned or arranged either substantially parallel to the x-axis (i.e. with axial alignment) or substantially parallel to the z-axis (i.e. with radial alignment).

The problem underlying the present invention therefore consists in enabling an automatable or autonomous detection or recognition of the orientation of a target magnet of an underlying BMP sensor or sensor system involved here. The invention is therefore intended to enable a BMP sensor to ascertain the axial/radial orientation of the target magnet automatically.

The invention is based here on the insight or finding that, after the target magnet has been positioned in a sensory detection area, the target orientation can be autonomously ascertained by the sensor, that is to say in particular even without any movement of the target magnet. For even more precise determining, recognizing or identifying of the most likely positive or negative, radial or axial target alignment or target orientation, however, only a brief movement of the target magnet can be carried out. It has also been recognized that it is also possible to determine the orientation of the target magnet irrespective of the rotation of the sensor array about its longitudinal axis.

In the method according to the invention for determining the orientation of a target magnet in a magnetic position sensor, in particular in a magnetic position sensor with a sensor array having a number of preferably at least three sensor elements, the following steps are provided according to a first aspect:
Gathering a number of magnetic vector data;
Calculating vector angle data from the gathered vector data and calculating progressions of the gathered vector data;
Monotonizing the calculated vector angle data for at least two predefined specific sets of circumstances, or case constellations respectively, that is to say by increasing or reducing individual angle values of the calculated vector angle data;
Excluding at least one of the at least two predefined specific sets of circumstances on the basis of the monotonized vector angle data;
Calculating expected progressions for non-excluded specific sets of circumstances;
Determining the orientation of the target magnet using the calculated progressions of gathered vector data and the calculated, expected progressions.

In the method according to the invention, provision can be made, according to a further aspect, for the orientation of the target magnet to be determined by comparing the similarity or correspondence between the calculated progressions of gathered vector data and the calculated, expected progressions.

In the method according to the invention, provision can be made, according to a further aspect, for in addition such specific sets of circumstances in which the monotonized vector angle data do not correspond to the vector angle data calculated from the gathered vector data to be excluded. It should be noted here that such a vector range of vector angle data corresponds to a respective specific set of circumstances.

In the method according to the invention, provision can be made, according to a further aspect, for the detected magnetic vector data to be transferred to an x-z plane through a rotating transformation and corresponding vector angles and vector lengths to be calculated from the data transformed in this way.

In the method according to the invention, provision can be made, according to a further aspect, for possible specific sets of circumstances to be ascertained from the corresponding vector angle data and vector length data.

In the method according to the invention, provision can be made, according to a further aspect, for the calculated vector angle data to be monotonized by adding values +/−2 Pi( ).

In the method according to the invention, provision can be made, according to a further aspect, for the calculated vector angle data to be shifted into ranges of currently determined specific sets of circumstances, that is to say by simultaneously adding and/or subtracting 2 Pi( ) to/from each angle value.

In the method according to the invention, provision can be made, according to a further aspect, for, when determining the orientation of the target magnet, similarity data between measured progressions and expected progressions to be calculated by comparing the similarity or correspondence between the calculated progressions of gathered vector data and the calculated, expected progressions.

In the method according to the invention, provision can be made, according to a further aspect, for the target magnet to be arranged in relation to a sensor element either according to a first set of circumstances below a line of arrangement of the sensor elements or according to a second set of circumstances above the line of arrangement.

In the method according to the invention, provision can be made, according to a further aspect, for eight possible specific sets of circumstances of the target magnet, which result from the first and second sets of circumstances and from the four possible main alignments of the magnetic moment of the target magnet.

In the method according to the invention, provision can be made, according to a further aspect, for the first and second sets of circumstances of the target magnet to be achieved by rotating the coordinate system of the position sensor about its x-axis.

In the method according to the invention, provision can be made, according to a further aspect, for the rotating transformation to be carried out by a rotation operation according to the method known per se of principal component analysis “PCA” of the y and z components of the gathered magnetic field vectors, that is to say the z-axis is rotated in the direction of the greatest distribution of data points. According to the PCA method, in the present case, the z-axis is rotated in the direction of maximum variability of the output signal of the target magnet and/or in the direction of the greatest distribution of data points. As a result, the y components of the magnetic field vectors are correspondingly minimized or eliminated in the resulting coordinate system. The x component of the magnetic field vector is disregarded here, i.e. the problem is transformed into the x-z coordinate system.

In the method according to the invention, provision can be made, according to a further aspect, for an ambiguity +/−2*Pi( ) to be resolved through a collective shifting of the measured vector angle values by a suitable integer multiple of a full angle.

The invention also relates to a computer program product comprising a computer-readable storage medium with a computer-readable program code incorporated therein, the computer-readable program code being configured such that it implements the abovementioned method.

The invention further relates to a device for operating a magnetic position sensor involved here according to the method described herein for determining the orientation of a target magnet.

The invention also relates to a magnetic position sensor which has or comprises a device for operating it according to the method described herein, that is to say for determining the orientation of a target magnet.

The invention enables effective and reliable automatic recognition of the alignment of a target magnet involved here, even if the sensor is shifted to the side or rotated during installation. In a BMP sensor or BMP sensor system involved here, the invention also enables the alignment of the target magnet to be independently recognized at any desired point within the sensory detection area, in particular even without any user interaction.

The invention enables the orientation of the target magnet to be determined using only one single measurement, i.e. in particular even without the target magnet moving, that is to say by means of a suitable algorithm operating as a function of orientation. As a result, the sensor or the sensor system can operate properly right from first switch-on.

The rapid determining of the target magnet orientation can also be used for or contribute to the self-diagnosis of a BMP system, e.g. for automatically recognizing the configuration of the BMP system.

Furthermore, the invention can also lead to a considerable reduction in the cost of an underlying BMP sensor system since it enables a greater distance between the sensor elements and precise and reliable detection beyond the measurement limits of the underlying sensor.

The invention also offers the user of such a BMP sensor system greater benefit since it enables a shorter installation time, fewer sources of faults during installation and immediate operational readiness.

### BRIEF DESCRIPTION OF THE DRAWINGS

Exemplary embodiments of the invention are shown in the drawings and are explained in more detail in the following description.

In the figures:

FIG. 1 schematically shows the spatial arrangement of a magnetic position sensor with a sensor array having three sensor elements;

FIG. 2 schematically shows a y-z plane of a position sensor involved here, using a pneumatic cylinder as an example;

FIG. 3 schematically shows a movement of a virtual magnet sensor along a line in the x-z plane shown in FIG. 1 near a dipole magnet;

FIGS. 4a, b schematically show a position measurement arrangement in an isometric representation and in a plan view of the x-z coordinate system shown in FIG. 1;

FIGS. 5a, b show possible magnetic alignments of a target magnet for different application scenarios;

FIG. 6 shows how a measurement arrangement, suitable for a specific application situation, of a position sensor involved here can be ascertained;

FIGS. 7a-f show a dipole field suitable for the method described here;

FIGS. 8a, b show how configurations/sets of circumstances (or cases) A or B shown in FIGS. 7a-7f can be excluded based on the angular range of measured angles which exists after monotonizing has been carried out corresponding to respective configuration A or B;

FIG. 9 shows angles measured using three sensor elements and correspondingly expected measurement curves;

FIG. 10 shows the determining of the similarity between measurement curves based on their progression;

FIG. 11 shows a flow diagram of the method according to the invention based on a first exemplary embodiment;

FIG. 12 shows a graphic overview of the method steps of the second exemplary embodiment represented in the following FIG. 13 using a flow diagram; and

FIG. 13 shows a flow diagram of the method according to the invention based on a second exemplary embodiment.

### DESCRIPTION OF EXEMPLARY EMBODIMENTS

A position indicator involved here must in most cases be axially polarized. However, the orientation of the corresponding target magnet (or the corresponding target object), i.e. whether the north pole or the south pole is pointing in the direction of the end of the sensor arrangement in the form of a cable, is irrelevant here.

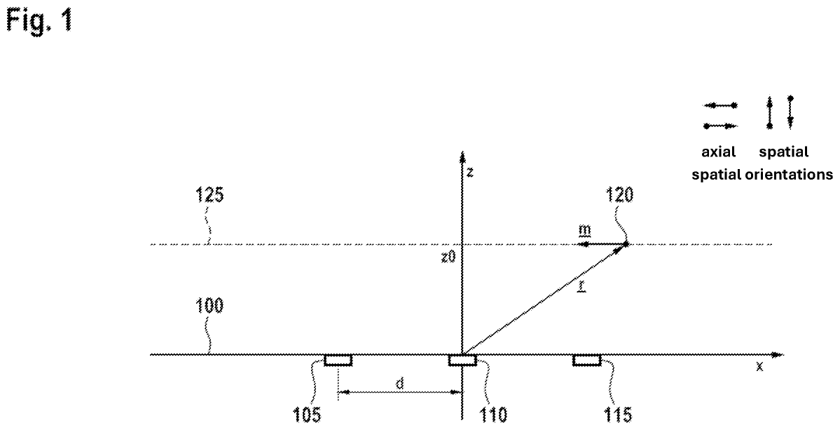

FIG. 1 schematically shows, using an x-z coordinate system spanning an x-z plane, the spatial arrangement of a magnetic position sensor with, by way of example, a linear sensor array 100 having three sensor elements 105, 110, 115.

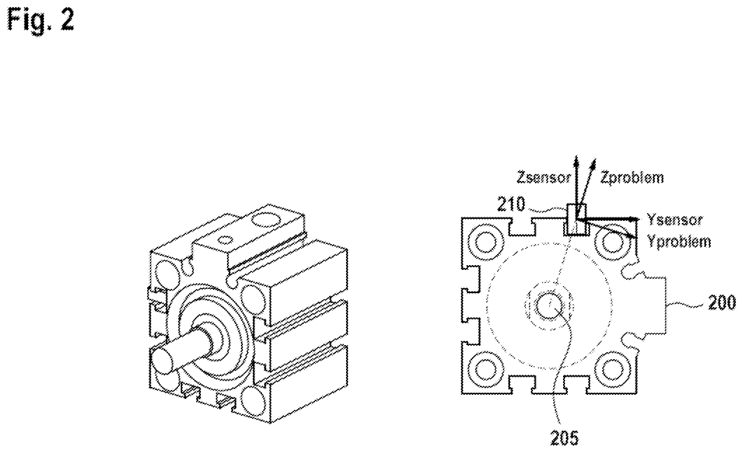

The three sensor elements 105-115 arranged in the present case on the x-axis are each at a distance d from one another. A target magnet 120 is moved in the z direction, that is to say parallel to the x-axis, at a distance z0 from the x-axis. Owing to its spatial orientation, the target magnet 120 has a magnetic moment m oriented in the present case parallel to the x-axis and in the linear direction of movement 125 of the target magnet 120. However, it should be noted that the orientation, as described below based on FIG. 2, can be tilted, e.g. as a result of assembly. The location vector of the target magnet which changes during movement in the present coordinate system has the respective length r and the respective angle α.

FIG. 2 then illustrates how the problem underlying the invention can preferably be represented in the x-z plane. This is because, during assembly of a sensor 210 involved here, the cylindrical axis 205 of a pneumatic cylinder 200 of a position indicator involved here does not automatically fit into the y-z plane shown in FIG. 2 (in the present case the same as the plane of the paper). This is because the magnet arranged in the piston of a pneumatic cylinder is usually an axisymmetric magnet which induces a magnetic field which has substantially only radial and axial components. Instead, a shown lateral shift occurs which is substantially equivalent to rotating the coordinate system of the sensor 210 about its x-axis (x-axis is perpendicular to the plane of the paper).

The radial component r of the magnetic “B-field” vector shown is divided up between the y and z coordinates of the sensor, which can be compensated for by transforming the detection plane of the sensor 210 into the x-z plane through corresponding opposite rotation about the x-axis.

The approach according to the invention described herein is based on the following two technical considerations or key aspects.

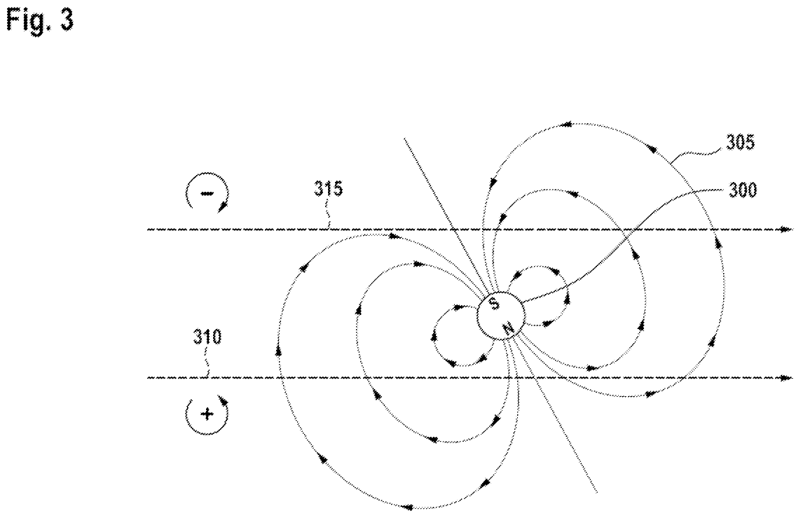

As illustrated in FIG. 3, when continuously moving along any desired line 310, 315 in the x-z plane shown in FIG. 1 near a dipole magnet 300 involved here with a dipole moment existing in the x-z plane, a virtual observer experiences a continuous, monotonous rotation of the magnetic field vector in a direction within a 2π range.

FIG. 3 shows two corresponding virtual lines of movement. The three vector angles α1, α2 and α3 that can be detected here represent not just simple angles here, but rather a correspondingly existing monotonous triplet of angles which rotates to the left or right depending on the side of the magnet on which this movement takes place.

If one therefore measures three vector angles α1, α2 and α3 and three vector lengths r1, r2 and r3 at the positions of the three sensor elements shown in FIG. 1 and provided next to the target magnet arranged with a first orientation, it is very unlikely that, in a different situation in which the target magnet is arranged in a different orientation, the same vector angles and vector dimensions will be measured. As a result, it is advantageous to know which regular orientation of a dipole magnet gives the same or at least the most similar proportions for measured vector angles to the proportions of the respective measured sizes. This is because such a regular orientation is the most likely orientation.

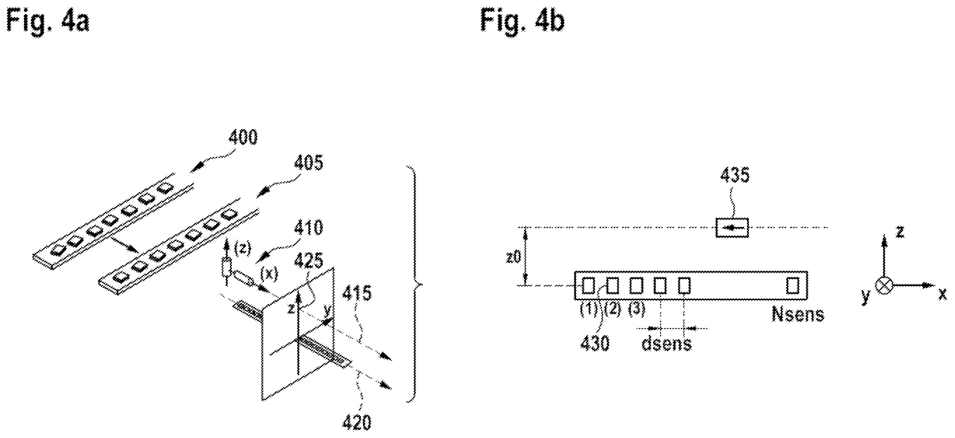

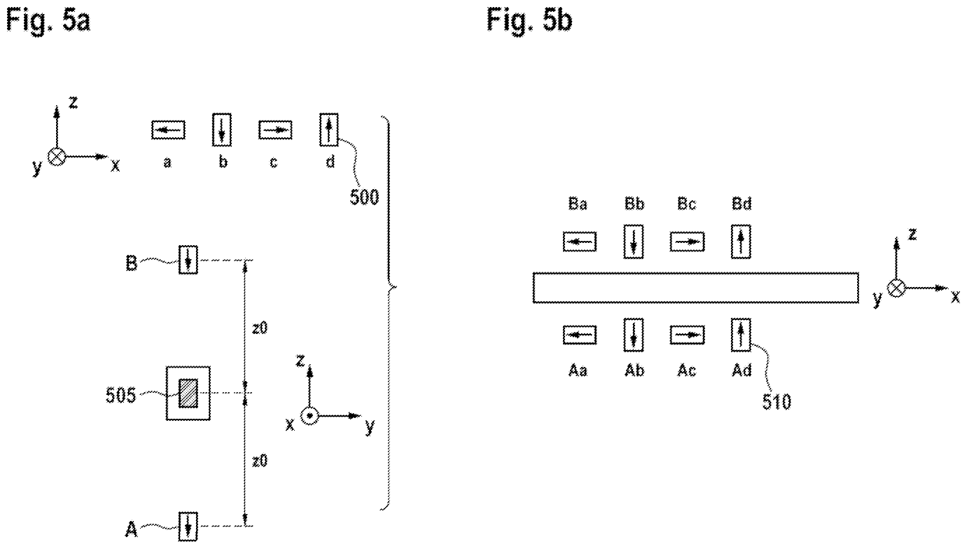

FIGS. 4a and 4b schematically show, by way of example, a position measurement arrangement both in an isometric representation (FIG. 4a) of an x-z coordinate system 410 shown in FIG. 1 and in a plan view (FIG. 4b) of an x-z coordinate system shown in FIG. 1. The direction of movement 415 of a target magnet 435 here is either in the direction A or direction B shown in FIG. 5a, i.e. below or above a sensor array 405. As can be seen from FIG. 4a, the target magnet 435 substantially moves in the regular z-direction 425.

As can also be seen from FIG. 4a, the sensor array 405 is the result of a correction of an industrially mass-produced sensor array 400. The arrangement of the sensor elements is already preset here during its production so that, for each sensor element, the sensitive axes of the microchips are aligned parallel to the x-, y- or z-axis of the scanning device.

However, if serious faults have been made during production, the alignment of the sensorily active axes of each of the sensor chips of the sensor array 400 which are already soldered on a printed circuit board can optionally be ascertained and a correspondingly corrective rotation transformation can be calculated. In normal operation, the respective corrective rotation transformation is applied to the measured magnetic field vector individually for each sensor chip. This correction produces an arrangement of magnetic field vectors which would also be produced in a sensor array 405 with correctly aligned sensors. The rotation and inclination errors occurring during assembly can therefore be corrected individually for each chip.

As can be seen from FIG. 4b, the number of sensor elements of the array in this exemplary embodiment is Nsens, the sensor elements being arranged along the x-axis shown, corresponding to FIG. 1, at respective distances dsens from one another. The distance between the line of movement 415 of the target magnet 435 and the line of arrangement 420 of the sensor elements 430 is substantially constant in this exemplary embodiment and corresponds, as in FIG. 1, to the value z0.

FIGS. 5a and 5b illustrate possible magnetic alignments of a target magnet 500 for different application scenarios.

As can be seen from FIG. 5a, the magnetic moment of the target magnet 500 can be aligned in one of the main alignments a, b, c or d here, i.e. corresponding to the directions of magnetization a, b, c or d shown in FIG. 5a above. With respect to a sensor element 505 shown, the target magnet 500 can be arranged either below the line of arrangement 420 of the sensor elements 430 shown in FIG. 4a according to set of circumstances A, or case constellations A, respectively. Alternatively, the target magnet 500 can be arranged above the line of arrangement 420 according to set of circumstances B.

FIG. 5b shows all eight of the application situations or corresponding sets of circumstances of a target magnet 510 under consideration here, in each case only one of these application situations being applicable. These eight scenarios are the result of the possible combinations of the two sets of circumstances A and B and from the four possible main alignments a, b, c or d of the magnetic moment of the target magnet 500.

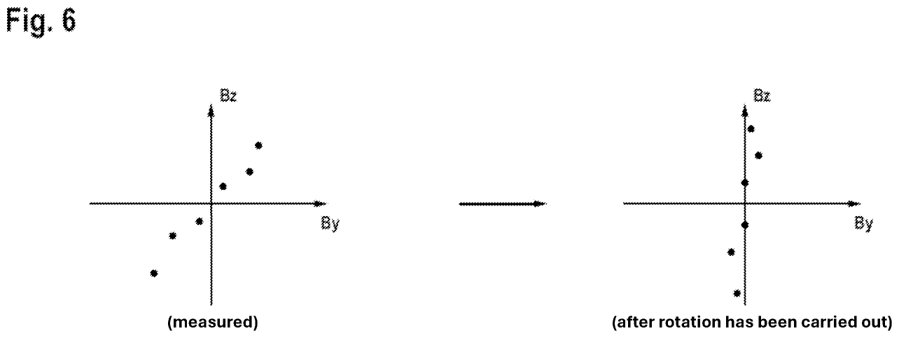

FIGS. 6a and 6b show how a measurement arrangement, suitable for a specific application situation, of a position sensor involved here can be ascertained.

It is therefore possible that the two application scenarios or sets of circumstances A or B shown in FIG. 5a can only be achieved by rotating the coordinate system of the sensor about its x-axis. This is possible even though the line of movement of the target magnet is arranged parallel to the measurement arrangement (as shown e.g. in FIG. 1). I.e. any other target object, i.e. any corresponding location vector, must be rotated in said y-z plane. In particular, the vectors of the magnetic flow density must also be correspondingly rotated about the x-axis.

FIG. 6 shows, on the left, six measurement points produced during a magnetic measurement and, on the right, the corresponding six measurement points after rotation has been carried out. A corresponding, suitable rotation or rotation operation can be determined using the known method of “principal component analysis” (PCA) of the y and z components of the gathered magnetic field vectors.

It should be mentioned that, owing to the ambiguity +/−Pi( ) of the angle of rotation of the rotational transformation, which substantially transforms the gathered flow density vectors into the x-z plane, both said A arrangements and said B arrangements can result. Both the further steps of the algorithm according to the invention for determining the orientation and of the algorithm for evaluating the target magnet position can therefore work with the transformed flow density vectors. This has the technical effect or advantage that the orientation to be determined and the transformed vectors remain consistent with one another. If, on the other hand, use is made of the angle of rotation of the smallest absolute value among the valid angles of rotation for the rotation transformation, the resulting A or B situation also remains consistent with respect to the underlying physical situation.

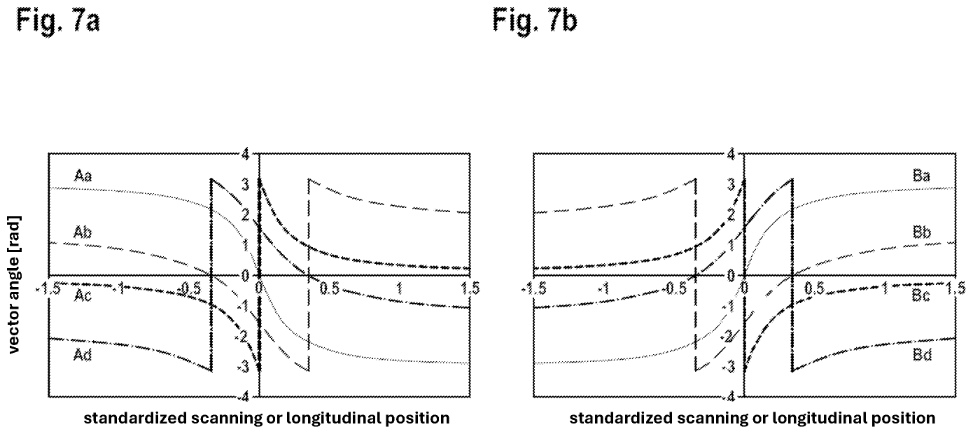

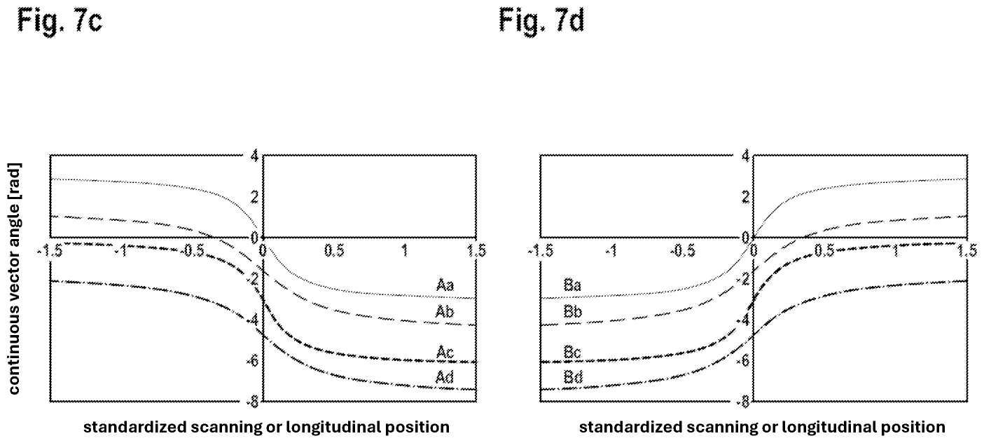

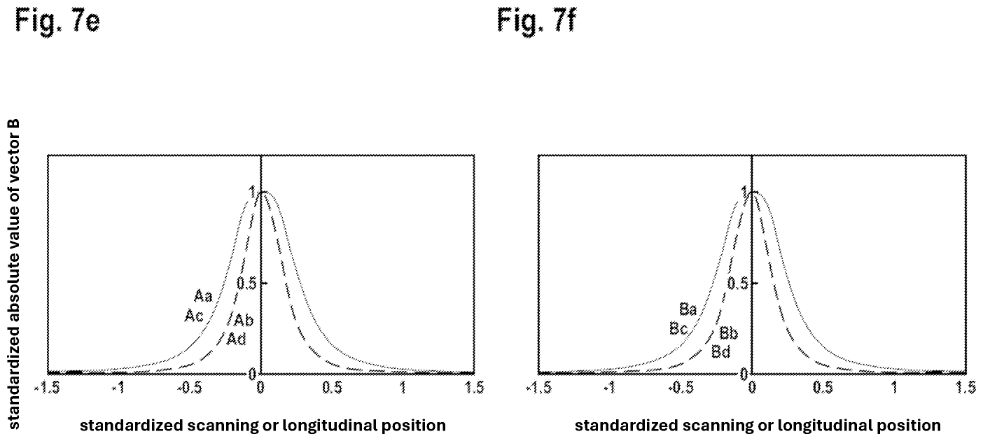

FIGS. 7a-7f show a dipole field suitable for the method described herein.

FIGS. 7a and 7b therefore show the angle of the measurable B vector above (FIG. 7a) and below (FIG. 7b) a dipole magnet involved here as a function of a standardized scanning or longitudinal position xsens with the constant z value z0 shown in FIG. 1. These values correspond here to the distance of the respective observation with regard to the central position of the target magnet. The different curves shown here correspond here to the different alignments or orientations of the target magnet.

FIGS. 7c and 7d show the above vector angles without rotation having been carried out, the ambiguity +/−2*Pi( ) being resolved through a collective shifting of the measured vector angle values by a suitable integer multiple of a full angle. The monotony of the continuous vector angle curves corresponds to the observation already described on the basis of FIG. 2 that, when moving along a constant z path (in the present case =z0) above or below a target magnet lying thereunder, an observer would observe a monotonous rotation of the B vector in the corresponding direction. The permissible value range for the vector angles with respect to alignment a is (−π, +π) for the b, c and d type alignments shown here, but the limits are smaller by the values π/2, π and 3π/2.

FIGS. 7e and 7f show the size of the magnetic vector B, that is to say standardized to its respectively largest value along a scan along the x-axis shown in FIG. 1, again at a constant distance of z0.

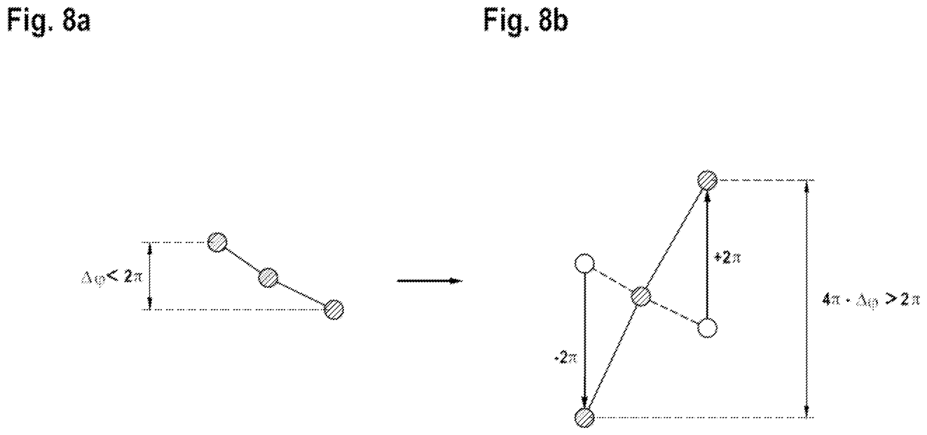

FIGS. 8a and 8b show measured angles and corresponding, measured measurement curves of the magnetic B field by three sensor elements, as shown e.g. in FIG. 1. With a number Nsens of sensor elements, such magnetic field sensors supply a series of measured flow density vectors {Bxj, 0, Bzj}j=1 . . . . Nsens. The flow density vectors are converted into corresponding vector angles, e.g. by application of an arctan 2 function, as already shown in FIGS. 7a and 7b.

Since the vector angles themselves necessarily have values between +Pi( ) and −Pi( ) the monotony of the vector angle values described above can be achieved by adding or subtracting 2*Pi( ) to or from the corresponding angle values. This adding or subtracting is carried out here until the monotony according to a respectively concerned application situation, i.e. from Aa to Bd, is achieved. If the number of sensors Nsens is 3, the first and the third sensor values are affected by the monotonizing method.

As can also be seen from FIGS. 8a and 8b, in the present exemplary embodiment with Nsens=3, three corresponding angle values which are obtained from a measurement can be monotonized both in ascending and in descending order. However, one of the two results here has to include values with a difference of more than 2*Pi( ). This is because such a result indicates that the assumption of monotony has not been met and that the target magnet is obviously not arranged corresponding to the corresponding case A or B (shown in FIGS. 7a-7f). FIG. 8a shows here a decreasing triplet of angle values and FIG. 8b shows an increasing counterpart monotonized once again.

Based on such a triplet (with the three sensor elements under consideration here), the form or the progression or the shape of such a measurement curve therefore corresponds to an ordered triplet of the three absolute values of the magnetic B vector which correspond to the three sensor elements if Nsens=3.

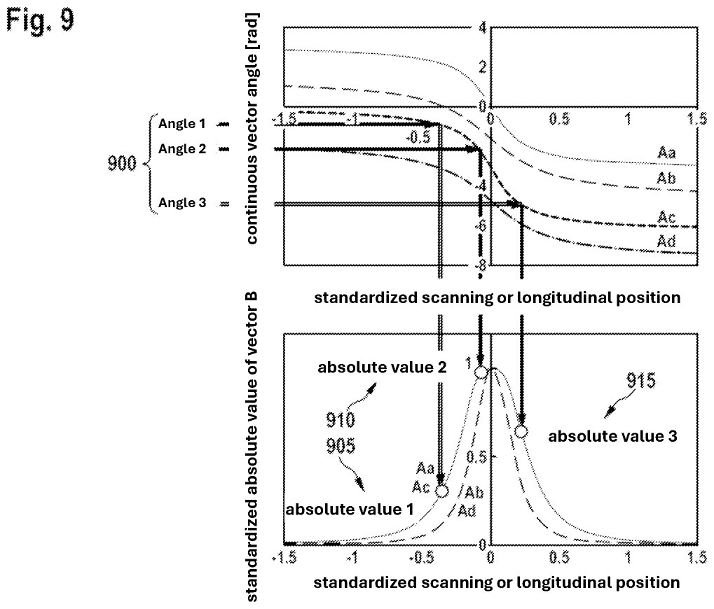

FIG. 9, again based by way of example on three sensor elements, shows for example measured angles 900, that is to say together with correspondingly expected measurement curves. After monotonizing, in the present case four cases are directly excluded, and only the remaining four cases (Aa-Ad or Ba-Bd in FIGS. 7a-7f) are examined more closely in order to ascertain the most likely alignment of the target magnet.

For each possible alignment from a to d, the monotonous triplet of angle values 900 shown here is shifted by an integer multiple of 2*Pi( ). As a result, the alignment is adjusted to the limits of a continuous vector angle curve, that is to say against a normalized scanning position of a given alignment, so that its monotony is retained. Alignments in which this adjustment is not possible are likewise excluded from the further examination in the present case.

The correspondingly monotonized and shifted angle values are localized on the corresponding measurement curve. The standardized absolute values for each scanning or sensor element corresponding to the standardized scanning position values ascertained are ascertained from the standardized amount-over-scanning position curve which therefore corresponds to the case actually examined. The correspondingly arranged triplet 905, 910, 915 of ascertained, i.e. standardized absolute values is then treated as the “expected curve shape” of such a measurement curve.

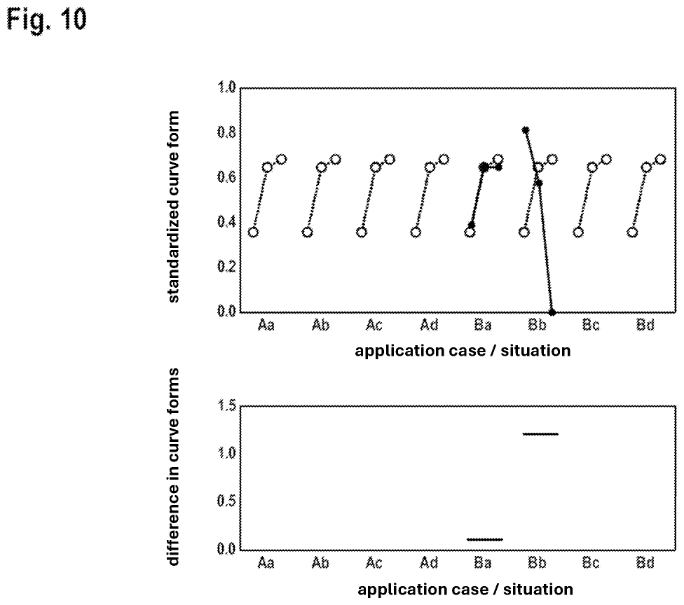

FIG. 10 illustrates an example of a method for determining the similarity between measurement curves described above, i.e. the similarity in terms of their shape or progression. For simplicity, the measurement curves shown here again consist of in each case only three measurement points detected by the three sensor elements shown in FIG. 1 (see the open and closed circle symbols).

In the method shown only schematically, the measured curve progressions are compared with expected curve progressions of non-excluded alignments (as just described). It is assumed here that an expected curve form or curve shape which corresponds to a real alignment is most similar to the respective measured curve form. However, this assumption is made even if perfect correspondence cannot be expected owing to the non-ideality of the target magnet and a possible minor misalignment compared to a regular alignment.

Since the height of a measured curve form depends on the strength and the distance of the target magnet, the measured curve forms must initially be brought to the same scale when standardizing the expected curve form. As a result, the measured and the expected curve forms are standardized individually, e.g. by dividing their values by their largest value, or by the square root of the sum of their values, or by their mean value, or another sensible size which characterizes their scalar size scale. As a result, a standardized measured curve form and the standardized expected curve forms are obtained.

The similarity of the two standardized curve forms is then characterized by their difference, i.e. the smaller the difference, the greater the similarity between the curve forms. The difference can be calculated either by adding up the absolute values of the differences between the respective links of the standardized measured curve form and the standardized expected curve form or by calculating the square root from the sum of the squares of these differences. However, other mathematical formulae for characterizing the difference between the curve forms are also conceivable.

The example shown in FIG. 10 then shows the standardized measured three values as hollow dots and the standardized expected values or corresponding patterns as full dots for a Bb type alignment. Cases in which the standardized expected patterns are not shown have been excluded here. The standardized measured patterns are repeated for visual comparison. The connecting lines serve merely as a visual orientation aid.

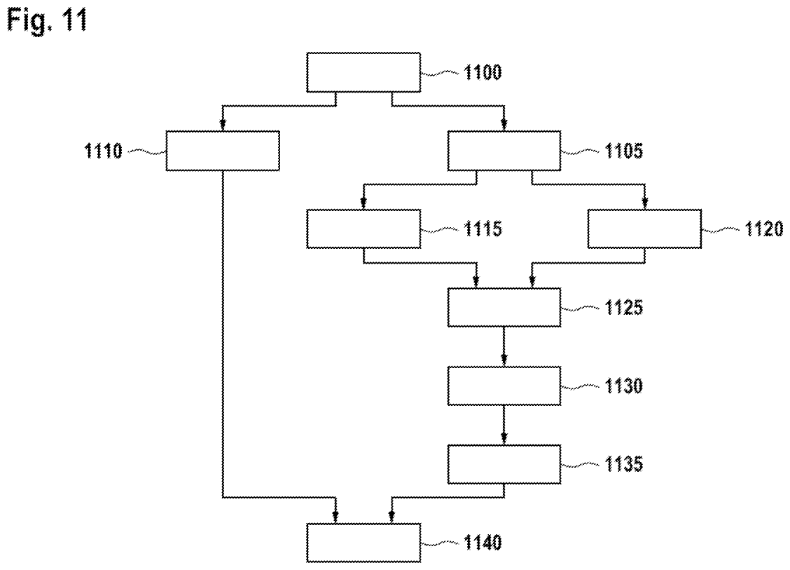

FIG. 11 shows the described method based on a first exemplary embodiment.

First of all, in this exemplary embodiment, said, by way of example, three B vectors (i.e. the data triplet 1, 2, 3) are measured 1100. On the one hand, the corresponding vector angle data are then calculated 1105 from the vector data therefore present. On the other hand, the corresponding said patterns or progressions of the gathered vector data are calculated 1110.

The vector angle data calculated in step 1105 are then, on the one hand, monotonized 1115 for said specific set of circumstances A, or case constellations A, respectively, that is to say in the present example by correspondingly increasing individual angle values of the data triplet involved. On the other hand, these vector angle data are monotonized 1120 for said specific set of circumstances B, that is to say again by correspondingly increasing some of the angle values of individual values of the data triplet involved.

On the basis of the data monotonized in the two steps 1115 and 1120, one of the two specific sets of circumstances A and B is then excluded 1125. Then, those specific sets of circumstances in which the monotonized vector angle data do not correspond to the measurement curves are likewise excluded 1130. Then, for the specific sets of circumstances remaining, i.e. for those not already excluded, expected curve forms or in the present case corresponding triplets of dot are calculated 1135.

Finally, based on the measured curve forms calculated in step 1110 and the expected curve forms calculated in step 1135, the specific set of circumstances for the target magnet orientation for which the measured curve form and the expected curve form have the greatest correspondence or similarity is determined 1140.

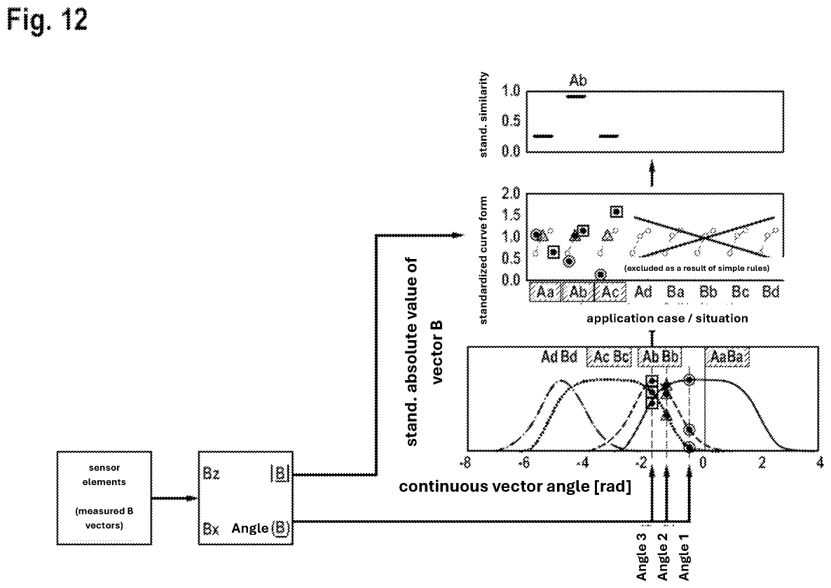

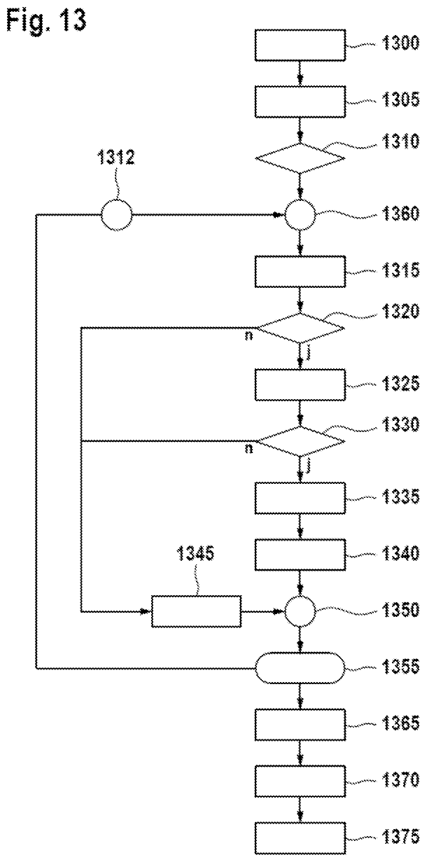

FIGS. 12 and 13 show the described method in more detail on the basis of a second exemplary embodiment. The method is again used to find out which spatial alignment or orientation of a correctly arranged dipole magnet (in a position measurement system or position sensor involved here) produces the pattern (or shape) most similar to a measured pattern or a measured shape of measurement points.

FIG. 13 shows the method (according to the second exemplary embodiment) for the autonomous or automatable determining of a target magnet orientation involved here using a flow diagram of a process routine, the method steps therein also being provided with correspondingly ascribed reference signs in FIG. 12.

First of all, in this exemplary embodiment, said three B vectors (1, 2, 3) are measured 1300, including carrying out said transformation or rotating transfer of the underlying problem to the x-z plane. The corresponding, measured vector angles and vector lengths are calculated 1305 from the data transformed in this way. Said eight specific situations for the sizes A and B and the alternatives a, b, c and d are ascertained 1310 from the vector data thus present.

A number of process steps are then carried out in the form of a program loop 1312.

In a first process step 1315, the vector angles present are monotonized by being reduced or increased in the way described above. Monotonizing is carried out according to the currently existing values Aa to Bd, that is to say by adding values +/−2 Pi( ) to the values present on the left and/or right as described above.

It is then checked 1320 whether the first process step 1315 was successful, i.e. whether the monotonizing has delivered a usable result. If not, the specific situation ascertained is characterized 1345 as “defective”.

However, if the first process step 1315 was successful, then the process is continued with the existing data in a second process step 1325 in which the existing vector angles are shifted into ranges of the currently determined specific sets of circumstances (or case constellations) a, b, c or d by simultaneously adding and/or subtracting 2 Pi( ) to/from each angle value.

It is then checked 1330 again whether the second process step 1325 was also successful, i.e. whether the shifting of the existing vector angles to ranges of the currently determined specific sets of circumstances a, b, c or d has delivered usable results. If not, the specific situation ascertained is again characterized 1345 as “defective”.

However, if the second process step 1325 was also successful, then the process is continued with the existing data in a third process step 1335 in which, for the existing vector angles, more accurate amounts for the currently existing specific set of circumstances according to the expected curve shape described above are called up. This calling up is carried out either directly on the basis of standardized amounts compared to predefined relationships for the vector angles or by determining standardized measurement positions of the sensor elements described above.

Then, in a fourth process step 1340, as described above, similarity data between the measured curve shapes, or said dot patterns, and the expected curve shapes/dot patterns are calculated.

Then, the program loop 1312 described is either repeated and the process goes back to the previous program step 1360, or else it is ended 1355, that is to say if all possible specific sets of circumstances have already been processed in way described. After the ending 1355 of the program loop 1312, first of all the specific situations declared “defective” are excluded 1365.

Then, those specific sets of circumstances not excluded in the previous step and having given the greatest correspondence values during the similarity check described are searched 1370. Finally, the specific set of circumstances, i.e. A or B, or a, b, c or d, found as described is output 1375 as the gathered magnet orientation or arrangement.

1. Method for determining an orientation of a target magnet in a magnetic position sensor with a sensor array having a number of at least three sensor elements, said method comprising the steps:
gathering a number of magnetic vector data;
calculating vector angle data from the gathered magnetic vector data and calculating progressions of the gathered magnetic vector data;
monotonizing the calculated vector angle data for at least two predefined specific sets of circumstances by increasing or reducing individual angle values of the calculated vector angle data;
excluding at least one of the at least two predefined specific sets of circumstances on a basis of the monotonized vector angle data;
calculating expected progressions for non-excluded specific sets of circumstances;
determining an orientation of the target magnet using the calculated progressions of gathered vector data and the calculated expected progressions.

2. The method according to claim 1, wherein the orientation of the target magnet is determined by comparing similarity or correspondence between the measured progressions of gathered vector data and the calculated, expected progressions.

3. The method according to claim 1, wherein in addition such specific sets of circumstances in which the monotonized vector angle data do not correspond to the vector angle data calculated from the gathered vector data are excluded.

4. The method according to claim 1, wherein the gathered magnetic vector data are transferred to an x-z plane through a rotating transformation and corresponding vector angles and vector lengths are calculated from the data transformed in this way.

5. The method according to claim 4, wherein possible specific sets of circumstances are determined from the corresponding vector angle data and vector length data.

6. The method according to claim 1, wherein the calculated vector angle data are monotonized by adding values +/−2 Pi( ).

7. The method according to claim 6, wherein the calculated vector angle data are shifted into ranges of currently determined specific sets of circumstances by simultaneously adding and/or subtracting 2 Pi( ) to/from each angle value.

8. The method according to claim 2, wherein, when determining the orientation of the target magnet, similarity data between measured progressions and expected progressions are calculated by comparing the similarity or correspondence between the calculated progressions of gathered vector data and the calculated, expected progressions.

9. The method according to claim 1, wherein the target magnet is arranged in relation to a sensor element either according to a first set of circumstances below a line of arrangement of the sensor elements or according to a second set of circumstances above the line of arrangement.

10. The method according to claim 9, wherein by eight possible specific sets of circumstances of the target magnet which result from the first and second sets of circumstances and from four possible main alignments of a magnetic moment of the target magnet.

11. The method according to claim 10, wherein the first and second sets of circumstances of the target magnet are achieved by rotating a coordinate system of a position sensor about its x-axis.

12. The method according to claim 4, wherein the rotating transformation is carried out by a rotation operation according to the method of principal component analysis “PCA” of the y and z components of the gathered magnetic field vectors, the z-axis being rotated in a direction of maximum variability of an output signal of the target magnet and/or in the direction of a greatest distribution of data points.

13. The method according to claim 12, wherein an ambiguity +/−2*Pi( ) is resolved through a collective shifting of the measured vector angle values by a suitable integer multiple of a full angle.

14. Computer program product, comprising a computer-readable storage medium with a computer-readable program code incorporated therein, the computer-readable program code being configured such that it implements a method for determining an orientation of a target magnet in a magnetic position sensor with a sensor array having a number of at least three sensor elements comprising the steps:
gathering a number of magnetic vector data;
calculating vector angle data from the gathered vector data and calculating progressions of the gathered vector data;
monotonizing the calculated vector angle data for at least two predefined specific sets of circumstances, that is to say by increasing or reducing individual angle values of the calculated vector angle data;
excluding at least one of the at least two predefined specific sets of circumstances on the basis of the monotonized vector angle data;
calculating expected progressions for non-excluded specific sets of circumstances; and
determining the orientation of the target magnet using the calculated progressions of gathered vector data and the calculated, expected progressions.

15. Device for operating a magnetic position sensor according to a method for determining the orientation of a target magnet the method comprising the steps:
gathering a number of magnetic vector data;
calculating vector angle data from the gathered vector data and calculating progressions of the gathered vector data;
monotonizing the calculated vector angle data for at least two predefined specific sets of circumstances, that is to say by increasing or reducing individual angle values of the calculated vector angle data;
excluding at least one of the at least two predefined specific sets of circumstances on the basis of the monotonized vector angle data;
calculating expected progressions for non-excluded specific sets of circumstances; and
determining the orientation of the target magnet using the calculated progressions of gathered vector data and the calculated, expected progressions.

16. Magnetic position sensor, characterized by a device for operating a position sensor according to a method comprising the steps:
gathering a number of magnetic vector data;
calculating vector angle data from the gathered vector data and calculating progressions of the gathered vector data;
monotonizing the calculated vector angle data for at least two predefined specific sets of circumstances, that is to say by increasing or reducing individual angle values of the calculated vector angle data;
excluding at least one of the at least two predefined specific sets of circumstances on the basis of the monotonized vector angle data;
calculating expected progressions for non-excluded specific sets of circumstances; and
determining the orientation of the target magnet using the calculated progressions of gathered vector data and the calculated, expected progressions.
